(19) United States
(12) Patent Application Publication
(10) Pub. No.: US 2026/0297808 A1
(43) Pub. Date: Oct. 1, 2026

(54) APPARATUS AND METHOD OF FORMING A COLLOID CONTAINING LAYER

(71) Applicants: Sze Chieh Yvonne TAN, SINGAPORE (SG); Vicknesh SAHMUGANATHAN, Singapore (SG); Brian K. KIRKPATRICK, Sunnyvale, CA (US); Abhijit Basu MALLICK, Fremont, CA (US); John SUDIJONO, Singapore (SG)

(72) Inventors: Sze Chieh Yvonne TAN, SINGAPORE (SG); Vicknesh SAHMUGANATHAN, Singapore (SG); Brian K. KIRKPATRICK, Sunnyvale, CA (US); Abhijit Basu MALLICK, Fremont, CA (US); John SUDIJONO, Singapore (SG)

(73) Assignee: Applied Materials, Inc., Santa Clara, CA (US)

(21) Appl. No.: 19/309,219

(22) Filed: Aug. 25, 2025

Related U.S. Application Data
(60) Provisional application No. 63/777,490, filed on Mar. 25, 2025.

(51) Int. Cl. C30B 29/04; C30B 25/18; C30B 25/20

(52) U.S. Cl. CPC C30B 29/04; C30B 25/186; C30B 25/20

(57) ABSTRACT

A method and system for depositing diamond particles on semiconductor substrates includes delivering a cleaning solution to form a clean substrate surface, applying a first rinsing solution, and delivering a colloidal solution containing diamond particles while applying sonic energy. The sonic energy is provided by a transducer to prevent particle agglomeration and ensure uniform distribution across the substrate surface. The method includes delivering a second rinsing solution to remove excess colloidal material followed by heating the substrate to promote adhesion of the diamond particles through Van der Waals forces. Various embodiments include delivering the colloidal solution through immersion, aerosol jet spray nozzles, or through nozzles with integrated sonic capabilities. The process may be performed in integrated processing systems with multiple chambers for cleaning, deposition, and heating operations, providing an automated manufacturing solution for creating uniform diamond seed layers used in thermal management applications for microelectronic devices.

### CROSS-REFERENCE TO RELATED APPLICATIONS

This application claims the benefit of U.S. provisional patent application Ser. No. 63/777,490, filed Mar. 25, 2025, which is herein incorporated by reference.

### BACKGROUND

### Field

The present technology relates to methods, components, and apparatuses for semiconductor manufacturing. More specifically, the present technology relates to a deposition process sequence that is configured to deposit colloidal materials on a surface of a semiconductor substrate.

### Description of the Related Art

In semiconductor manufacturing, the need for effective heat dissipation becomes increasingly crucial as device dimensions continue to shrink and device power densities rise. Diamond films, with their superior thermal conductivity, have emerged as promising candidates for heat conducting layers in microelectronic applications. To grow high-quality diamond films, a uniform seed layer of nanocrystalline or microcrystalline diamond particles must first be deposited on the substrate surface.

Common approaches to deposit colloidal solutions on solid substrates include spin-coating, sonication, electrochemical deposition, spray deposition, and sol-gel methods. However, the majority of these methods have not been proven feasible at 300 mm substrate-scale and are not intended for high volume manufacturing (HVM). Additionally, methods such as sonication of substrates in colloidal solutions have been shown to abrase substrate surfaces, causing micro-damage that can compromise device performance.

Current processes for coating nanocrystalline diamond particles onto substrate surfaces, whether at coupon-scale or substrate-scale, typically involve manual pre-cleaning of the substrate in chemical baths prior to prolonged sonication of the substrate in the diamond particle containing solution. These processes are followed by a series of manual rinsing and drying steps that are time-consuming and difficult to standardize.

A significant challenge in the deposition of nanocrystalline diamond particles is that these particles tend to agglomerate or clump together, resulting in a non-uniform distribution of a deposited layer. Additionally, achieving strong adhesion between the particles and the substrate surface is important for subsequent processing steps. Existing methods struggle to simultaneously address the issues of uniform distribution, particle agglomeration, and surface adhesion while maintaining substrate integrity.

Another limitation of current processes is their incompatibility with modern semiconductor manufacturing flows, which require automated, integrated solutions that can process substrates at a high throughput and reproducibility. The manual nature of conventional approaches creates bottlenecks in production and introduces variability that negatively impacts yield.

Therefore, there is a need for an improved method for uniformly depositing colloidal materials, particularly nanocrystalline diamond seed particles, onto semiconductor substrates in a manner that is compatible with high-volume manufacturing, prevents substrate damage, ensures uniform distribution, and can be integrated into existing semiconductor processing equipment.

### SUMMARY

The present disclosure generally relates to methods, apparatus, and systems for uniformly coating colloidal materials containing diamond particles onto semiconductor substrates. In particular, embodiments of the disclosure provide integrated processing solutions that enable uniform deposition of nanocrystalline diamond seed particles and other colloidal materials in a manner compatible with high-volume semiconductor manufacturing requirements.

In one embodiment, a method of depositing a layer is provided. The method includes delivering a cleaning solution to a surface of a substrate to form a clean surface of the substrate, delivering a first rinsing solution to the cleaned surface of the substrate to form a rinsed surface, and delivering a colloidal containing solution, which comprises diamond particles, to the rinsed surface of the substrate. Delivering the colloidal containing solution comprises delivering, by a transducer, sonic waves to the colloidal containing solution while delivering the colloidal containing solution to the rinsed surface to form a colloidal material containing layer that comprises the diamond particles. The method further includes delivering a second rinsing solution to the colloidal material containing layer formed on the surface of the substrate, and heating the colloidal material containing layer and the substrate to a first processing temperature. This integrated process sequence ensures uniform distribution of diamond particles while preventing particle agglomeration through the controlled application of sonic waves.

In another embodiment, a method of depositing a layer is provided that utilizes a multi-chamber processing system. The method includes delivering, in a first processing chamber of a processing system, a cleaning solution to a surface of a substrate to form a clean surface on the substrate, and delivering, in the first processing chamber, a first rinsing solution to the clean surface of the substrate. The substrate is then transferred from the first processing chamber to a second processing chamber disposed within the processing system. The method further includes delivering, in the second processing chamber, a colloidal containing solution, which comprises diamond particles, to the rinsed surface of the substrate to form a colloidal material containing layer on the rinsed surface, wherein delivering the colloidal containing solution comprises delivering a waveform (e.g., sonic waves) to the colloidal containing solution while delivering the colloidal containing solution to the rinsed surface. A second rinsing solution is delivered, in the second processing chamber, to the surface of the substrate that includes the colloidal material containing layer. The substrate is then transferred from the second processing chamber to a third processing chamber disposed within the processing system, where heating of the colloidal material containing layer and substrate to a first processing temperature is performed. This configuration enables efficient substrate processing while maintaining separation between distinct chemical processes.

In yet another embodiment, the colloidal containing solution may be delivered to the substrate through different means, including immersing the substrate into the colloidal containing solution or dispensing the colloidal containing solution onto the rinsed surface of the substrate through an aerosol jet spray nozzle configured to combine the colloidal containing solution with a stream of gas. Alternatively, the colloidal containing solution may be delivered through an exit port of a nozzle as a stream to the rinsed surface, with the transducer configured to provide a waveform (e.g., sonic waves) to the stream of the colloidal containing solution. The diamond particles may comprise nanocrystalline diamond seed particles suspended in a solvent, with the nanocrystalline diamond seed particles having a size distribution range of 2 nanometers to 200 nanometers.

In still another embodiment, the colloidal containing solution may be prepared by combining a first solution that comprises a first concentration of the diamond particles in a first solvent and a second solution, which comprises the first solvent, to form the colloidal containing solution, wherein the concentration of the diamond particles in the first solvent in the formed colloidal containing solution is less than the first concentration of diamond particles. The substrate may be positioned on a rotatable support within the processing chamber and rotated at a speed between 50 RPM and 1500 RPM while delivering the colloidal containing solution from a dispensing arm, with the rotational speed of the dispensing arm adjusted to match an angular velocity of the rotating substrate at different radial positions to provide uniform exposure time to the colloidal containing solution across the rinsed surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a schematic diagram of an integrated processing system, according to one or more embodiments of the disclosure.

FIG. 1B illustrates an expanded integrated processing system that includes multiple processing platforms, according to one or more embodiments of the disclosure.

FIG. 2A illustrates a schematic cross-sectional view of a wet-processing module that can form part of an integrated processing system, according to one or more embodiments of the disclosure.

FIG. 2B illustrates a schematic view of a portion of the wet-processing module, according to one or more embodiments of the disclosure.

FIG. 2C illustrates a top view of a portion of the wet-processing module, according to one or more embodiments of the disclosure.

FIG. 2D is a schematic illustration of a jet nozzle disposed within the wet clean module, according to some embodiments.

FIG. 3 illustrates a side view of a wet-processing module that can form part of an integrated processing system, according to one or more embodiments of the disclosure.

FIG. 4 illustrates a detailed view of a thermal processing and/or contamination removal chamber that can form part of an integrated processing system, according to one or more embodiments of the disclosure.

FIG. 5 illustrates a schematic diagram of a plasma processing chamber that can form part of an integrated processing system, according to one or more embodiments of the disclosure.

FIG. 6 illustrates a process flow diagram, according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to methods and systems for uniformly depositing colloidal materials onto a surface of a substrate. Some embodiments of the disclosure include integrated processing solutions that enable uniform deposition of a colloidal material containing film layer in a manner compatible with high-volume semiconductor manufacturing requirements. In some embodiments, the colloidal material containing film layer will include nanocrystalline diamond seed particles or other useful colloidal materials. In some embodiments of the disclosure, a colloidal material deposition process sequence is performed in an integrated processing tool.

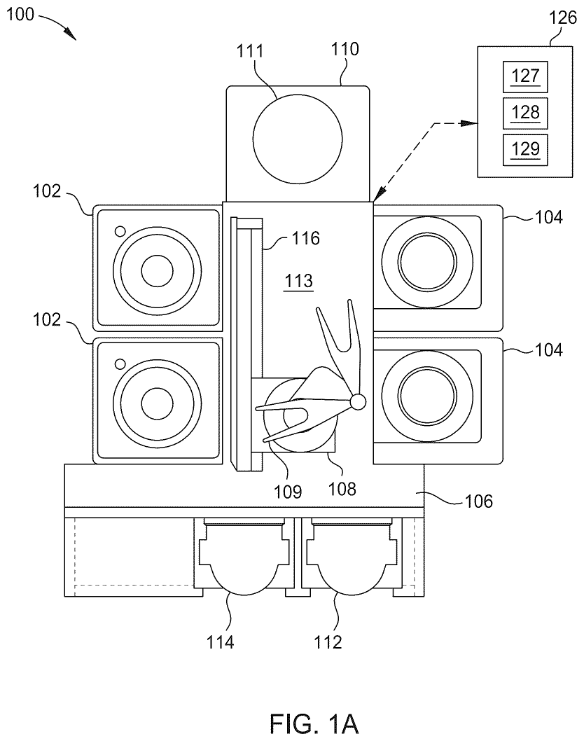

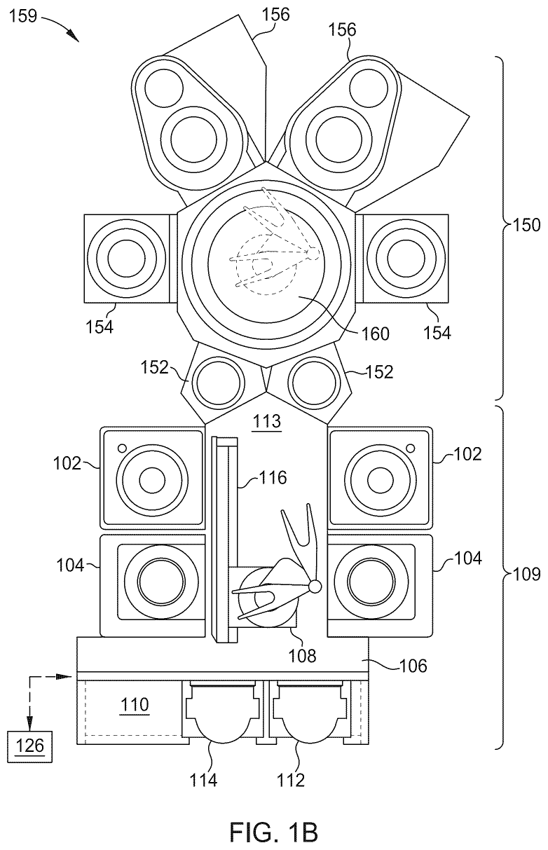

Referring now to FIG. 1A, a processing system 100 for implementing the methods described herein is illustrated. The processing system 100 comprises a plurality of first wet-processing chambers 102, second wet-processing chambers 104, a thermal processing chamber 110, and a substrate handling system 106. The substrate handling system 106 includes a robot 108 that facilitates substrate movement within a central transfer chamber 113 that serves as the hub connecting all processing modules. As discussed further below, the first wet-processing chambers 102 and second wet-processing chambers 104 can include similarly configured wet processing chambers or wet processing chambers that are specifically adapted to perform different aspects of the processing method 600 described below. The thermal processing chamber 110 can include a heated substrate support 111. The processing system 100 also includes a first front-opening-unified-pod (FOUP) 112 and a second FOUP 114, with a mechanical component 116 that facilitates the lateral movement of the robot 108. This integrated configuration enables sequential substrate processing without exposure to external environments, providing complete “dry-in to dry-out” processing capability that significantly reduces contamination risk while improving throughput compared to conventional standalone equipment.

FIG. 1B illustrates an expanded processing system 159 for integrated substrate processing that combines a lower platform 109 with an upper platform 150 to provide enhanced processing capabilities. The lower platform 109 comprises multiple integrated processing chambers including: wet-processing chambers 102 for substrate cleaning operations; substrate wet-processing chambers 104 for depositing colloidal materials, such as nanocrystalline diamond seed particles, on a surface of a semiconductor substrate; a thermal processing chamber 110; a substrate handling robot 108 for transferring substrates between chambers; a central transfer chamber 113 that serves as a central hub for substrate movement within the processing system 100; first FOUP 112 and a second FOUP 114; and a robot 108 and transfer mechanism 116 that facilitates substrate movement between the platforms. The upper platform 150 extends the processing capabilities by incorporating additional chambers including: load lock chambers 152 for transitioning substrates between atmospheric and vacuum environments; additional film deposition chambers 154 for specialized layer formation; and specialized treatment chambers 156 for substrate processing operations such as etching, annealing, or other treatments. A dedicated central transfer mechanism 160, which includes a vacuum-compatible robot (not shown), within the upper platform 150 coordinates substrate movement between the upper chambers, while integration with the lower portion of the processing system 100 is maintained through the substrate transfer mechanism 116. This multi-platform configuration enables simultaneous processing of multiple substrates through diverse process sequences while maintaining environmental isolation between atmospheric and vacuum processing steps, thereby significantly enhancing throughput and processing flexibility.

A system controller 126 controls the operation of any of the multi-chamber processing tools and/or processing chambers described herein, including the processing system 100 and the expanded processing system 159, and at least processing chambers 102, 104, 110, 200, 328, 400, and 550. The controller 126 may directly control the multi-chamber processing tool and processing chambers, or alternatively, by controlling the computers (or controllers) associated with the multi-chamber processing tool and processing chambers. In operation, the controller 126 enables data collection and feedback from the multi-chamber processing tools and chambers to optimize their performance and to control the processing flow according to methods described herein. The controller 126, as schematically illustrated in FIG. 1A, generally includes a central processing unit (CPU) 127, a memory 128, and a support circuit 129. The CPU 127 can be any form of a general-purpose computer processor that can be used in an industrial setting. The support circuit 129 is conventionally coupled to the CPU 127 and may comprise a cache, clock circuits, input/output subsystems, power supplies, and the like. Software routines, such as methods as described above, may be stored in the memory 128 and, when executed by the CPU 127, transform the CPU 127 into a specific-purpose computer (controller 126). The software routines may also be stored and/or executed by a second controller (not shown) that is located remotely from the multi-chamber processing tools and processing chambers.

The memory 128 is in the form of computer-readable storage media that contains instructions, when executed by the CPU 127, to facilitate the operation of the semiconductor processes and equipment. The instructions in the memory 128 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present disclosure.

### Processing Chamber Examples

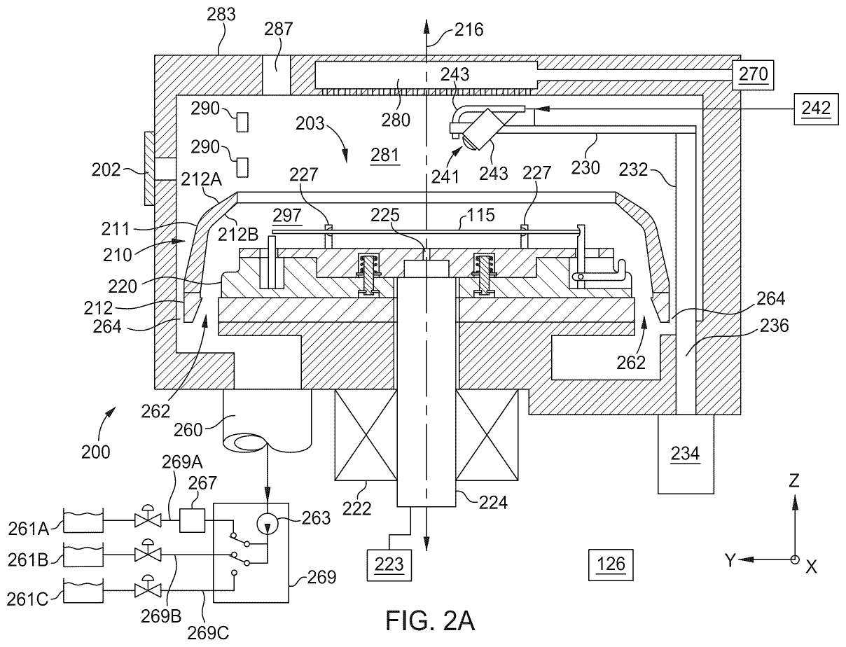

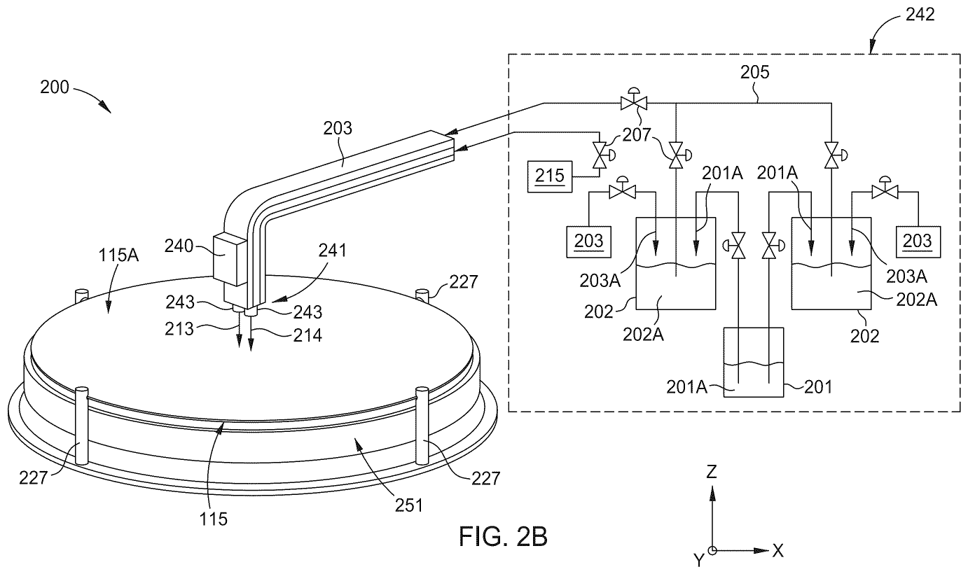

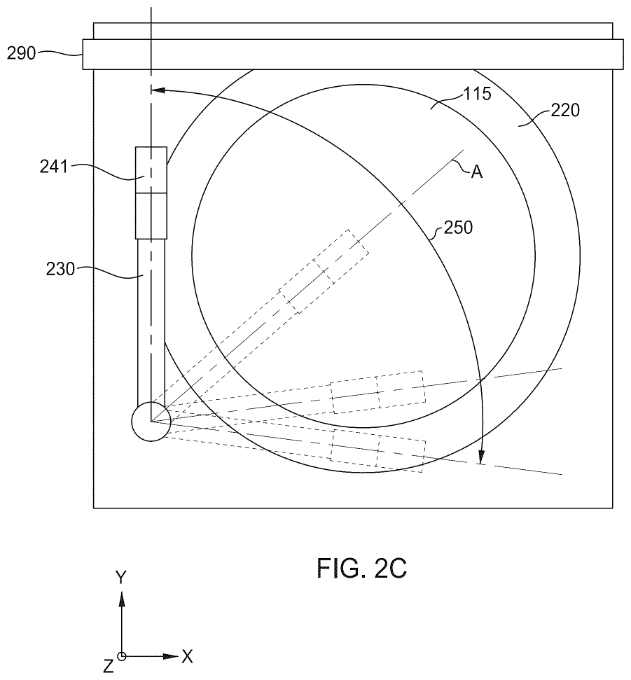

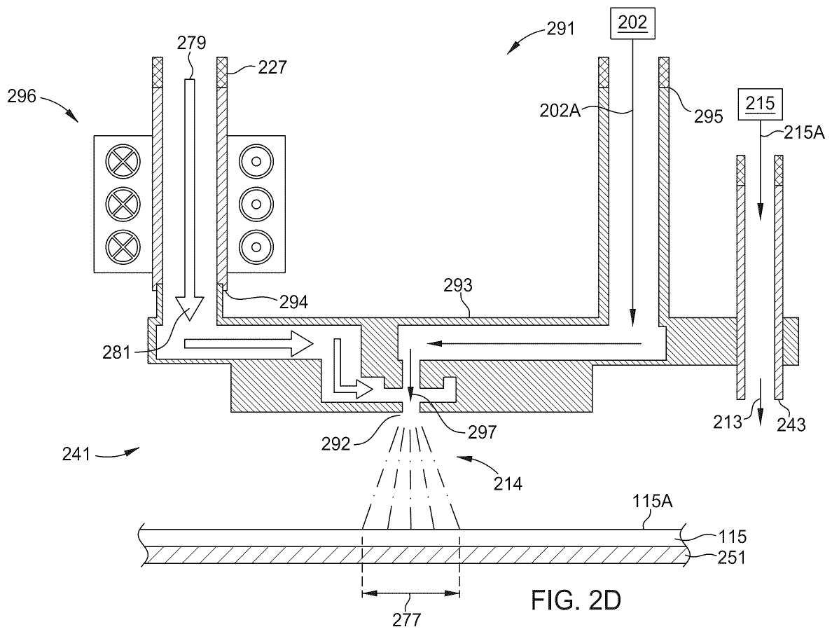

FIG. 2A illustrates a wet-processing module 200 that can be positioned within and/or form part of one of the wet-processing chambers 102 or 104 described above. As shown in FIG. 2A, the wet-processing module 200 comprises a substrate gripping device configured to support a substrate 115 in a horizontal orientation. The wet-processing module 200 includes a catch cup 210 comprising a first catch cup portion 211 and a second catch cup portion 212, with the catch cup having a wall 212A that contains an annular inner surface 212B defining a processing region 297. The substrate gripping device includes a gripper assembly 220 for securing the substrate during processing. A drive motor 222 is coupled to a shaft 224 that extends through the wall 212A and connects to the gripper assembly 220, enabling rotation about rotational axis 216 and vertical movement of the gripper assembly 220. The gripper assembly 220 will include a plurality of mounting brackets 227 that are configured to support and retain a substrate 115. The shaft 224 includes an opening 225 for delivering wet-processing fluids from a fluid source 223 to the backside of the substrate. The wet-processing module 200 will include a plurality of mounting brackets 227 (FIGS. 2A and 2B) that are adapted to support substrate during processing within the wet-processing module 200. The module features a fluid delivery arm 230 connected to a fluid delivery arm shaft 232 that is driven by a fluid delivery arm drive motor 234, allowing one or more of the nozzles 243 of the nozzle mechanism 241 to move in an arcuate path parallel to the front surface of the substrate for dispensing wet-processing fluids thereon. The nozzle mechanism 241 will include one or more nozzles 243 that are coupled to a fluid source 242.

The wet-processing module's airflow is controlled by a plenum 280 supplied by air intake 270, with a drain port 260 positioned to remove air and prevent particle recontamination. Drain holes 262 in the catch cup direct fluids to a drain port 260, while air flow components 264 further direct airflow within the module. The wet-processing system is contained within an enclosure wall 283 that defines an interior volume 281. Spray bars 290 positioned near the chamber entrance can apply fluids to the substrate during loading and unloading operations. A sensing device 287 monitors substrate presence and position within the wet-processing module 200.

During wet processing the gripper assembly 220 can be elevated by a motor to a processing position in which the substrate 115 is positioned within a desired region of the first catch cup 211. The first catch cup 211 is a structure extending inwardly from the enclosure side wall of the wet-processing module 200. At the processing position, as will be discussed further below, a fluid stream 214 that includes a first colloid containing fluid is delivered through a nozzle 243 of the nozzle mechanism 241 and onto the substrate surface 115A. After the solution flows over the substrate surface, the first catch cup 211 is adapted to collect the solution. The solution then flows through a fluid drain holes 262 and through the drain port 260, where the fluid is then pumped out of the wet-processing module 200 by use of a pump 263. The pumped fluid is then delivered selectively by a valve switching mechanism 269 to a respective collection tank 261A, 261B. The solution may be reclaimed once it is positioned within the collection tank 261A, 261B and/or recirculated to the solution fluid source 242, or the solution may even be discarded. Purifiers 267 may be coupled to one or more the outlets to filter, purify, or beneficially alter the costly components (e.g. colloid material) or environmentally unfriendly components (e.g. metals, complexing agents, etc.).

After processing, the substrate 115 may be moved to a rinsing position. A rinse fluid stream 213 (FIG. 2B) can be used to spray a rinse agent over the substrate 115. The rinse agent is drained through the rinse drain 260 and pumped out through outlet into a rinse agent reservoir 265.

In some embodiments, the wet-processing module 200 can include a sophisticated drain switching mechanism that includes drain holes 262 positioned strategically around the catch cup 210 to collect processing fluids as they're spun off the rotating substrate 115. These drain systems connect to a drain management infrastructure that separates different chemical streams through automated valve controls. The system can include separate drain paths for acids, bases, and colloidal solutions, directing each to appropriate collection or disposal systems. This separation is particularly important for the colloidal solution, which can be filtered, replenished, and recycled to reduce material costs, especially important given the value of nanocrystalline diamond particles. The drain switching is controlled through valve switching mechanism 269 (FIG. 2A) that includes automated valves that are activated by a system controller 126 based on the specific process being performed, preventing incompatible chemistries from mixing. The valve switching mechanism 269 can be an important part of the integrated processing system by enabling chemical segregation during the various wet processing steps performed in the wet-processing module 200. As schematically shown in FIG. 2A, separate drain pathways 269A-269C are implemented for acids, bases, and colloidal solutions. This separation is achieved through the use of a valve switching mechanism 269 that redirects fluid flows based on the process being performed. For example, as discussed further below, when delivering a SC1 cleaning solution (ammonium hydroxide, hydrogen peroxide, and water), the system activates the base chemistry drain path; when delivering a SC2 cleaning solution (hydrochloric acid, hydrogen peroxide, and water) or dilute HF, the system activates the acid chemistry drain path. In this example, the colloidal solution drain path remains separate from both acid and base paths, allowing for potential recovery and recycling of the valuable diamond seed material. This separation is essential not only for material conservation but also for safety, as mixing of certain chemicals could potentially form hazardous compounds or low-explosive chemical salts. The drain management system includes appropriate dilution and neutralization capabilities prior to final effluent discharge.

FIG. 2B illustrates a schematic partial isometric view of the processing assembly 200 of FIG. 2A that is adapted to perform a wet-process, such as cleaning a substrate and/or uniformly depositing a colloidal containing material. The processing assembly 200 comprises a circular housing 251 that includes a plurality of mounting brackets 227 that are disposed circumferentially about its perimeter and are configured to support and retain the substrate 115 during processing. A substrate 115 is positioned at location 115A in a substantially horizontal orientation relative to the circular housing 251. A fluid delivery arm 230 extends outwardly from the circular housing 251 and terminates at the nozzle mechanism 241, wherein the delivery arm 230 is configured to direct processing fluids onto the substrate surface by use of one or more of the nozzles 243.

To deliver one or more processing fluids to a substrate surface 115A during wet-processing, the processing assembly 200 further comprises the fluid source 242, which includes a first fluid source 215 that is configured to deliver a fluid stream 213 to a surface of the substrate 115. The fluid source 242 also includes one or more colloid containing fluid sources 202 that are configured deliver a fluid stream 214 that includes a first colloid containing fluid 202A to a surface of the substrate 115. In some embodiments, the first colloid containing fluid 202A has a first colloid containing concentration that has a first concentration of the diamond particles that are diluted in a first solvent 203A. The fluid source 242 also includes a second fluid source 201 that includes a second colloid containing fluid 201A. The second fluid source 201 is adapted to deliver the second colloid containing fluid 201A to each of the one or more colloid containing fluid sources 202. In some embodiments, the second colloid containing fluid 201A comprises a second concentration of the diamond particles that are diluted in the first solvent 203A. In some embodiments, the second colloid containing fluid 201A has a higher colloid containing concentration than the first colloid containing fluid 202A. The first colloid containing fluid 202A can be formed by diluting the second colloid fluid 201A with a fluid, such as the first solvent 203A, which is provided from a dilution source 203. In some embodiments, the dilution ratio of the second colloid solution 201A to total diluted fluid volume (i.e., total volume =volume of the second colloid fluid provided from the second fluid source 201 plus the volume of the added first solvent) can be greater than 10%, such as greater than or equal to 25%, such as greater than or equal to 50%, or even greater than or equal to 75%, or within a range between 10% and 75%, such as between 50% and 75%. The fluid handling network shown in FIG. 2B establishes predetermined fluid pathways to ensure the delivery of the pre-mixed colloidal solution to the nozzle mechanism 241, by use of the tubing 205 and a plurality of fluid control valves 207, to ensure proper fluid routing during each phase of the fluid delivery processes described below. The arrangement of these components enables sequential delivery of wet-processing solutions, rinsing solutions, and colloidal-containing fluid 202A to the substrate surface in accordance with the processing methods described herein, while maintaining the positional relationships between the nozzle mechanism 241 and the substrate 115 is used to achieve uniform deposition of colloidal materials.

In some embodiments, a storage vessel within the fluid sources 202 is configured to contain the first colloid-containing fluid 202A comprising nanocrystalline diamond seed particles suspended in an appropriate solvent. The nanocrystalline diamond particles can have a size distribution ranging from 2 nanometers to 200 nanometers, such as about 5 nanometer to about 80 nanometer. The particles are supplied in an original concentrated form of typically 2-5% weight per volume and are diluted at a dilution ratio ranging from 1:50 to 1:30,000 relative to the original concentration. In some examples, ratios of 1:50, 1:10,000, and 1:18,000 have been shown to be effective for various application requirements. In one example, the solvent 203A includes deionized water (DI water). While DI water may serve as the primary dilution medium, alternative solvents including isopropyl alcohol, DMAC, and DMSO may be employed depending on specific process requirements and compatibility considerations.

Complete mixing of the first colloid containing fluid 202A and/or second colloid containing fluid 201A with a solvent can be accomplished within the storage vessels through one of several agitation mechanisms. Alternatively, mechanical impeller systems may be utilized, with motor-driven impellers of appropriate design creating controlled turbulence patterns optimized for particle dispersion without introducing excessive air entrainment. For higher-precision applications, the storage vessel may incorporate an actuator 247 that includes a piezoelectric transducer that is configured to generate sonic energy to disperse and maintain separation of the nanocrystalline diamond particles before being dispensed on the surface 115A of a substrate 115. The piezoelectric transducers may be arranged in various configurations, such as: (1) positioned on the outside walls of the vessel that contains the first colloid containing fluid 202A; or (2) positioned on interior walls of the vessel that contains the first colloid containing fluid 202A. The piezoelectric elements are typically positioned below the liquid level to ensure effective energy transfer to the first colloid containing fluid 202A. In some embodiments of the system, the mixing functionality is confined entirely to the storage vessel, with no additional mixing mechanisms implemented downstream in the delivery path.

However, in some embodiments, the processing assembly 200 includes an actuator 240 that is configured to provide sonic energy to the stream 214, which can include the first colloid containing fluid 202A, as the fluid exits the nozzle and contacts the surface 115A of the substrate. In some embodiments, the actuator 240 includes a piezoelectric transducer that is coupled to fluid delivery arm 230. In some other embodiments, the actuator 240 is configured to provide sonic energy to either the stream 213, the stream 214 or both streams, as the fluids exit the respective nozzles 243 and contact the surface 115A of the substrate.

In some configurations, the actuator 240 and/or the actuator 247 are configured to generate a waveform (e.g., sonic waves) that has a frequency within a frequency range of 100 to 5000 kilohertz, which can be in the ultrasonic (100-800 kHz) or megasonic (800-5000 kHz) range, to disperse and maintain separation of the nanocrystalline diamond particles within the colloid containing fluid before the fluid is dispensed on the surface 115A of the substrate 115. In one example, frequencies at about 1.0 megahertz, plus or minus 0.2 megahertz, have demonstrated particular effectiveness in balancing dispersion performance with process stability. The power levels applied at these frequencies typically range from 100 watts to 1000 watts depending on vessel size, solution volume, and specific dispersion requirements. In one example, a power density is maintained between 0.1 and 1.0 watts per cubic centimeter of solution volume to ensure adequate energy for dispersion while avoiding excessive heating or solution degradation.

FIG. 2C illustrates a top view of the substrate wet-processing chamber configuration, showing the path of the fluid delivery arm 230 relative to the substrate 115 during a wet-processing process. The substrate 115 is shown in a horizontal orientation, being held securely by the mounting brackets 227 (FIGS. 2A-2B) of the gripper assembly 220. The fluid delivery arm 230 extends from one side of the chamber toward the substrate and supports the nozzle mechanism 241 at its end. As depicted by path 250, the fluid delivery arm 230 and attached nozzle mechanism 241 move in an arcuate trajectory that passes over the center of the substrate 115 during processing. This arcuate movement ensures uniform application of wet-processing fluids across the entire surface of the substrate. The spray bar 290 is positioned at the top of the chamber, providing additional fluid delivery capabilities during substrate loading and unloading operations. The configuration shown allows for precise control of the wet-processing fluid application by enabling adjustment of both the fluid delivery arm position and the distance between the nozzle mechanism and the substrate surface. During operation, the substrate 115 typically rotates while the fluid delivery arm 230 traverses across its surface, creating a comprehensive wet-processing pattern that ensures uniform fluid coverage across the entire substrate surface. In some embodiments, by use of commands provided from the system controller 126, the process of traversing the fluid delivery arm 230 across the surface of the substrate can be controlled to assure that a uniform distribution of a dispensed fluid is provided across the surface of the substrate. In one example, the fluid delivery arm 230 can be caused to sweep from a position at the center of the substrate to an edge of the substrate along a path that requires the fluid delivery arm's movement to vary as a function of the dispense nozzle mechanism's position along the radius of the substrate as the substrate is rotated under the fluid delivery arm 230. While the disclosure provided herein primarily discloses the use of a fluid delivery arm 230, one skilled in the art will appreciate that a separate fluid delivery dispense arms can be provided to separately distribute one or more of the process fluids described herein to the surface of the substrate during processing.

FIG. 2D illustrates a schematic cross-sectional view of a nozzle assembly 291 that can include an aerosol jet nozzle for delivering a processing fluid to a surface 115A of a substrate 115. In some embodiments, the nozzle is configured to deliver the fluid at an elevated temperature. The nozzle assembly 291 includes a nozzle orifice 292, a nozzle body 293, a first fluid inlet 294, a second fluid inlet 295, a heater 296, a nozzle 243, and a mixing region 297. As shown, a first fluid 279 flows through the heater 296 from the first supply line 298 and enters into the nozzle body 293 through the first fluid inlet 294. A second fluid enters into the nozzle body 293 through the second fluid inlet 295 from the second fluid source. In one example, the first colloid containing fluid 202A enters into the nozzle body 293 through the second fluid inlet 295 from a colloid containing fluid sources 202. In an alternate example, a first rinsing fluid (e.g., DI water and/or cleaning chemistry) enters into the nozzle body 293 through the second fluid inlet 295 from a first fluid source 215. A third fluid 215A, such as a rinsing fluid, is delivered from a first fluid source 215 and to the surface of the substrate 115 through a nozzle 243. The first fluid 279 and second fluid (e.g., first colloid containing fluid 202A or rinsing fluid) mix in the mixing region 297 to form a fluid mixture that is provided in the fluid stream 214. The fluid mixture is dispensed from the nozzle body 293 through the nozzle orifice 292 such that the fluid mixture forms an aerosol of the sprayed fluid mixture. The fluid mixture dispensed from the nozzle orifice 292 forms a mixture diameter 277 on the surface 115A of the substrate 115. The mixture diameter 277 is defined by the diameter the fluid mixture creates when it contacts the surface 115A of the substrate 115 disposed in the processing assembly 200.

In certain embodiments, the first fluid 279 is a gas. For example, the first fluid 279 may be Argon (Ar), Nitrogen (N₂), Oxygen (O₂), or any combination thereof. In certain embodiments, the second fluid 279 is a liquid, such as the second fluid 279 may include DI water or a solvent, as will be discussed further below. In yet another example, the second fluid 279 may include DI water and a chemical solution configured to clean a substrate. In certain embodiments, the third fluid 215A is a liquid. For example, the third fluid 215A may be DI water or a solvent. The third fluid 215A can help maintain a fluid and/or liquid film on the surface 115A of the substrate 115 during a rinsing or cleaning operation.

In one embodiment, the first fluid 279 is delivered from a first fluid source (not shown), and enters the heater 296 at a first fluid temperature between about 10° C. and about 30° C. For example, the first fluid 279 enters the heater 296 at about 20° C. The heater 296 is a heating device configured to heat the first fluid 279. In some embodiments, the heater 296 is configured to heat a gas flowing therethrough so that the first fluid 279 leaves the heater 296 as a heated first fluid 281.

As shown in FIG. 2D, the second fluid, such as the first colloid containing fluid 202A, enters the nozzle body 293 at the second fluid inlet 295. In one embodiment, the second fluid enters the nozzle body 293 at a second fluid temperature between about 10° C. and about 60° C. For example, the second fluid may enter the nozzle body 293 at about 40° C.

The nozzle body 293 may include polyether ether ketone PEEK, PTFE, PVDF, PP, PE, HDPE, ULTEM, brass, stainless steel, a polymer, an alloy, a ceramic, or any combination thereof. The body includes the mixing region 297 and the nozzle orifice 292. The nozzle orifice 292 is in fluid communication with the mixing region 297, the first fluid inlet 294, and the second fluid inlet 295. In one embodiment, the nozzle orifice 292 includes a diameter between about 0.1 mm and about 2 mm. For example, the nozzle orifice 292 diameter may be about 1 mm. The nozzle orifice 292 is configured to spray the mixture toward the substrate surface 115A. In one embodiment, the sprayed mixture diameter 277, as discussed above, has an impact diameter where the sprayed mixture contacts the substrate surface 115A between about 3 mm and about 15 mm.

The nozzle assembly 291 may be configured such that the mixture is sprayed in an aerosol form. In some embodiments, the nozzle assembly 291 is an aerosol nozzle configured to supply the mixture to the substrate surface 115A. The substrate 115 can be rotated during a processing operation. Keeping the mixture in an aerosol form, instead of an atomized or vapor form, enables the mixture droplet to stay larger and thereby retain more of its heat when the mixture contacts the substrate surface 115A. For example, the mixture may have a droplet size between about 1 micron and about 20 microns when the mixture contacts the substrate surface 115A.

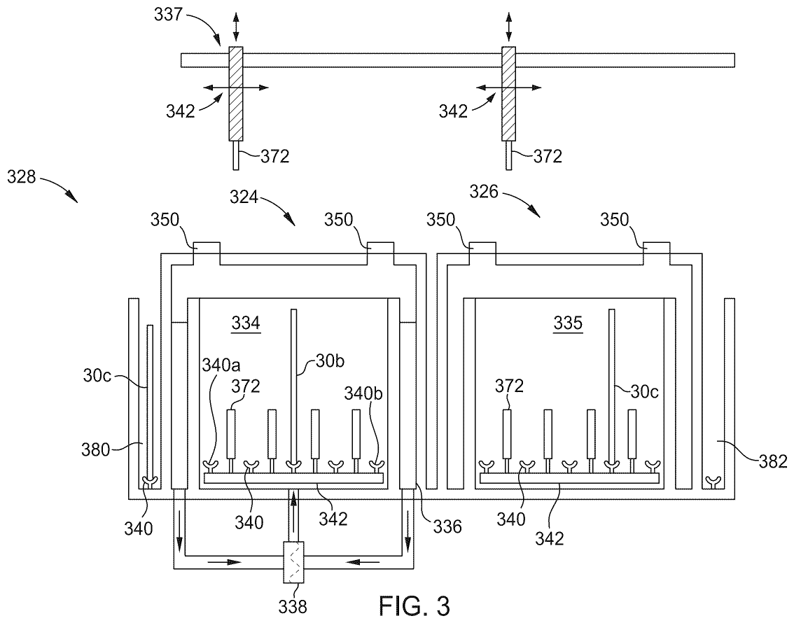

FIG. 3 illustrates a schematic cross-sectional view of a sulfuric-peroxide-mixture (SPM) cleaning system comprising dual processing chambers for substrate treatment. The SPM cleaning system includes a first cleaning container 324 and a second rinse container 326, positioned adjacent within a processing module 328. The processing module 328 can be coupled to one of the systems 100 or 159 for use within a processing sequence. A robotic transfer apparatus 337, which includes one or more walking beam mechanism 342, is positioned above the chambers for substrate handling. Both containers 324, 326 incorporate operable access ports 350 at their upper surfaces to facilitate substrate entry and exit while minimizing chemical exposure. The cleaning container 324 contains cleaning liquid 334 (e.g., sulfuric peroxide mixture) with distinct regions including primary solution 340a and secondary treatment zone 340b, while the rinse container 326 contains rinsing liquid 335 (e.g., DI water). Both chambers feature substrate support mechanisms 340 disposed along their lower portions to secure substrates 30b and 30c in vertical orientation during processing. Walking beam mechanisms 342 are positioned over the support mechanisms 340 in both chambers and are each configured to transfer a substrate in lateral and vertical directions. The walking beam mechanisms 342 will include substrate grippers 372 to transfer substrates between the substrate support mechanisms 340. The system includes overflow basins 336 surrounding the primary chambers to capture excess processing fluids. Processing fluid maintenance is provided through filtering, heating and replenishing system 338 connected to both chambers via fluid pathways. Substrate entry occurs at receiving station 380, with processed substrates exiting via output station 382 after completing the sequential cleaning and rinsing operations. Drainage and recirculation components direct fluid flow throughout the system as indicated by directional arrows. The entire assembly is housed within containment structures, or containers 324 and 326, which are designed to isolate processing chemicals while maintaining precise environmental conditions for optimal substrate treatment.

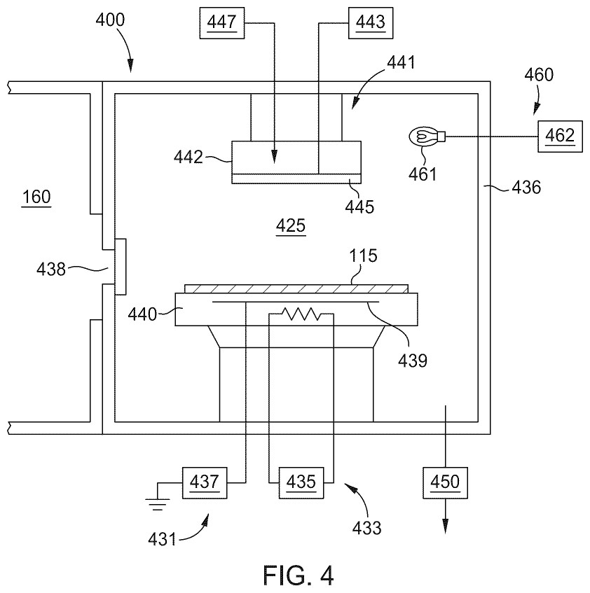

FIG. 4 illustrates a schematic cross-sectional view of a processing chamber 400 that is configured to perform pre-colloidal deposition and/or post-colloidal deposition processes on a substrate 115 that can include contaminant removal steps and/or thermal processing steps. The chamber 400 comprises chamber walls 436 that form a sealed processing environment that can be evacuated during one or more of the processes performed therein by an exhaust pump 450 (e.g., vacuum pump) and provides structural support for internal components. A slit valve 438 is positioned on the side of the chamber wall 436 to enable substrate transfer into and out of the enclosed processing region 425. The substrate slit 438 interfaces with the transport subsystem that moves substrates between different processing stations in the integrated system. A substrate chuck 440 is positioned within the processing region 425 and is mounted to the lower portion of the chamber wall 436 and provides a stable support surface for a substrate 115 during processing. The substrate chuck 440 is appropriately sized to accommodate a substrate that has a desired size (e.g., 200 mm, 300 mm, 450 mm, or larger diameter substrates) and incorporates an electrode 439 for biasing the substrate 115 during a plasma treatment performed by use of a bias assembly 431 that includes a radio frequency (RF) source 437.

The substrate chuck 440 can also include resistive heating assembly 433 that includes an AC power source 435. The heating assembly 433 and a radiant heating assembly 460, which includes one or more lamps 461 and a lamp power source 462, can be used to perform a thermal treatment on a substrate 115 during a pre-colloidal deposition and/or post-colloidal deposition process performed in the processing chamber 400.

Positioned at the upper region of the chamber is a source assembly 441 that includes an electrode 442 and plasma generator 443 that are used to create a plasma during a plasma processing step. In some embodiments, the electrode 442 of the source assembly 441 includes an electrode, or inductive coil, that is connected to the plasma generator 443 (e.g., RF power source) and gas distribution components 445 (e.g., showerhead) that introduce process gases delivered from a gas source 447 into the chamber. During a contaminant removal operation, the plasma generator 443 can be used to form a plasma that removes organic materials, surface oxides, and contaminants from the substrate surface. This plasma treatment is particularly important for preparing surfaces prior to colloidal deposition to ensure optimal adhesion of nanodiamond seed particles in downstream modules of the integrated system.

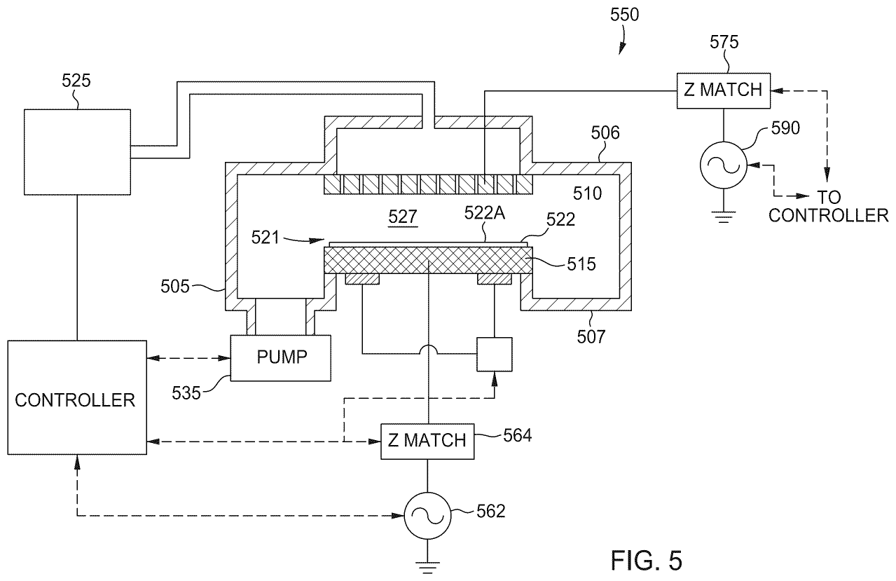

FIG. 5 illustrates a schematic cross-sectional view of a processing chamber 550 suitable for plasma-enhanced processing of substrates prior to or after the colloidal deposition process. In some embodiments, the plasma-enhanced processing can include a plasma enhanced deposition process such as a preclean process, reactive ion etching (RIE) process, plasma enhanced chemical vapor deposition process (PECVD), or PE atomic layer deposition (PEALD) process. The processing chamber 550 includes a chamber body having sidewalls 506 and a base 507, which collectively define a processing region 527 where substrate 522 is positioned during processing. A gas distribution showerhead 510 forms the upper boundary of the processing region 527 and includes a plurality of gas nozzle openings 530 through which process gases are delivered from a gas supply 525. A temperature-controlled substrate pedestal 515 supports substrate 522 and can be positioned at varying distances from the showerhead 510. The pedestal 515 is coupled to a bias RF generator 562 through an impedance match element 564, enabling plasma formation between the showerhead 510 and the substrate surface 522A. The showerhead 510 is connected to another RF power source 590 via an impedance match element 575. Process gases and reaction byproducts are removed from the processing region 527 through a vacuum port connected to a vacuum pump 535. A system controller 126 is connected to various components of the processing chamber 550 to regulate process parameters including gas flow rates, power levels, pressure, and temperature, ensuring optimal conditions for performing the preclean, plasma etching or deposition steps.

### Process Flow Example(s)

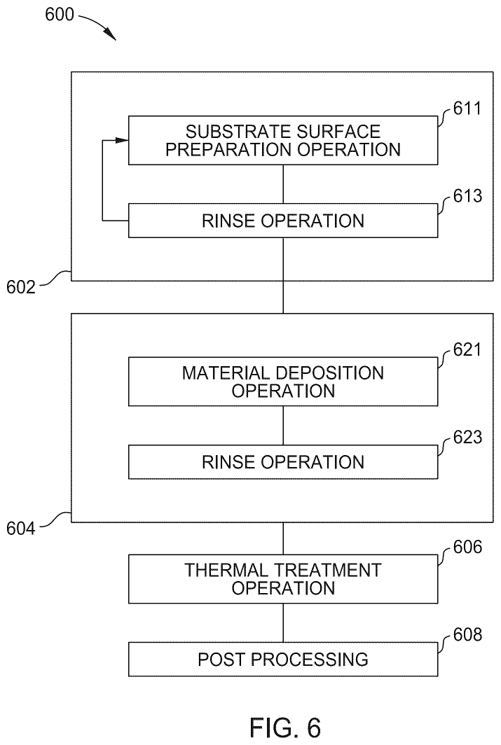

FIG. 6 illustrates a method 600 that includes a process flow that can be implemented in one or more system configurations. FIG. 6 depicts an example of a portion of a colloidal layer formation process flow, which can be used to form a portion of a semiconductor device. The operations performed during method 600 include a substrate processing sequence that can be performed by multiple processing modules, which include a substrate preparation operation 602, a material deposition operation 604, a thermal treatment operation 606, and an optional post-processing operation 608. The substrate processing sequences described in relation to method 600 can be implemented in a single chamber that performs all operations sequentially, a system with dedicated chambers for each major process step (e.g., cleaning, deposition, heating), or a fully compartmentalized system with separate chambers for each individual operation. The single-chamber approach offers advantages in floor space utilization, reduced capital equipment cost, and simplified substrate handling, but may have throughput limitations. The multi-chamber configuration provides higher throughput, better process isolation, and enhanced contamination control, though at higher system complexity and cost. The selection between these configurations depends on production volume requirements, available facility space, contamination sensitivity of the specific application, and the importance of process flexibility for accommodating different substrate types or process variations.

The system architectures, illustrated in FIGS. 1A and 1B, support multiple configuration options to accommodate different production requirements and facility constraints. In a fully compartmentalized configuration, each process step occurs in a dedicated chamber optimized for that specific operation, such as a configuration that includes separate chambers for SC1 cleaning, SC2 cleaning, HF treatment, first rinse, colloidal deposition, second rinse, and thermal processing. This approach maximizes cross-contamination control and process optimization but requires more floor space and capital investment. A semi-integrated configuration combines compatible process steps within shared chambers, for example, a single wet wet-processing chamber performs all wet-processing steps with intermediate rinses, a separate chamber handles colloidal deposition and post-deposition rinsing, and a third chamber performs the baking operation. This approach balances throughput, process isolation, and system footprint. In highly space-constrained environments, a single-chamber configuration can perform all operations sequentially within one processing vessel, though with reduced throughput. The modular nature of the system design allows for reconfiguration and expansion as processing needs evolve, with the transfer mechanisms and control systems accommodating various chamber arrangements. In one example, a processing vessel can include multiple separate fluid delivery dispense arms that can be used to separately distribute one or more of the process fluids to the surface of the substrate during processing.

Referring to FIG. 6, method 600 begins at substrate preparation operation 602 in which a surface 115A of a substrate 115 is prepared for the subsequent operations performed during the process sequence. In some embodiments, operation 602 includes a cleaning operation 611 and a rinsing operation 613 that can be performed one or more times before method 600 continues to the subsequent processing operations, such as operation 604.

The method 600 described herein can accommodate different substrate types beyond standard silicon substrates, including glass substrates, compound semiconductor substrates, packaging substrates, and metal-coated substrates. While the process has been primarily described with reference to circular substrates, it is equally applicable to rectangular panels with appropriate modifications, such as rectangular panels with dimensions ranging from 310 millimeters×310 millimeters to 600 millimeters×600 millimeters. In one example, a rectangular substrate has dimensions found in a range between 310 millimeters×310 millimeters and 510 millimeters×515 millimeters. For substrates with exposed metal layers, selective cleaning approaches may be employed that avoid chemistries that would attack the metal structures. Different substrate materials may require modifications to the cleaning sequence to ensure proper surface preparation without damaging the substrate.

The substrate preparation operation 602 can include a sequence of controlled chemical cleaning operations performed in a wet processing chamber. In some embodiments, operation 602 is performed in a processing assembly 200 which is positioned in a wet processing chambers 102 as shown in FIGS. 1A and 1B. In some embodiments, the processing sequence begins with operation 611 that can begin with an SC1 (Semiconductor Clean 1) cleaning process. The SC1 cleaning process utilizes a cleaning chemistry that includes ammonium hydroxide, hydrogen peroxide, and deionized water in ratios ranging from 1:1:500 to 1:2:500, delivered at temperatures between room temperature and 80 degrees Celsius to the surface 115A of a substrate 115. During application, the substrate is rotated at speeds between 50 RPM and 500 RPM while the fluid delivery arm 230 is positioned slightly offset from the center of the substrate 115, similar to orientation “A” of the fluid delivery arm 230 shown in FIG. 2C. It is believed that the exposure of the substrate surface 115A to the SC1 solution is helpful to remove organic contaminants from the substrate surface through oxidation reactions catalyzed by the alkaline environment and removes particulate contaminants through chemical etching and particle repulsion mechanisms.

Next, at operation 613, a stream 213 that includes a rinsing fluid is provided to a surface 115A of the substrate 115 positioned on a substrate supporting surface of a substrate support that is disposed within the processing assembly 200. The rinse fluid stream 213 (FIG. 2B) will include the delivery of a rinse agent, such as DI water, over the substrate surface 115A.

In some embodiments, following the first time that operations 611 and 613 are performed (e.g., first SC1 treatment and rinse with the rinsing agent), the substrate may undergo a second treatment cycle (i.e., recursive cycle) that includes a second cleaning agent operation and a rinse operation. In one example, the second performance of operation 611 can include the delivery of a dilute hydrofluoric (HF) acid to remove the oxide layer formed on a silicon-containing substrate, which was created during the SC 1 process. The dilute HF solution comprises 49% HF diluted with deionized water at ratios ranging from 1:50 to 1:1000, typically applied at room temperature while the substrate is rotated at speeds between 50 RPM and 300 RPM. As illustrated in the process flow diagram FIG. 6, the second operation 611 is followed by a rinse operation 613 in the first processing module before proceeding to the deposition operation 621 in the material deposition operation 604.

In some embodiments, following the first time and second time that operations 611 and 613 are performed, such as the SC1 treatment and rinse and the HF treatment and rinse, a subsequent SC2 (Semiconductor Clean 2) process may be implemented in a third performance of operation 611, which follows the dilute HF treatment and its associated rinse step. The third performance of operation 611 can include the delivery of a SC2 solution, which comprises hydrochloric acid, hydrogen peroxide, and deionized water at ratios typically between 1:1:200 and 1:2:500, at a temperature between 60 degrees Celsius and 70 degrees Celsius to the surface of the substrate surface 115A. The SC2 treatment is generally used to remove metallic contaminants from the substrate surface through formation of soluble metal complexes. Typically, the SC2 process is not implemented when metals are directly exposed on the substrate surface, as the chemistry would attack and potentially damage intentional metal structures. During SC2 application, the substrate typically rotates at speeds between 100 RPM and 400 RPM, with specific rotation rates selected based on substrate diameter and chemical distribution requirements.

In another embodiment, an alternate version of the third performance of operation 611 can include an implementation of a sulfuric peroxide mixture (SPM) cleaning process, also referred to as the “Piranha” process, can be performed on the substrate. The SPM solution comprises concentrated sulfuric acid and hydrogen peroxide at ratios ranging from 3:1 to 10:1, with common implementations utilizing approximately 4:1 or 5:1 ratios. Due to the exothermic reaction between the components, SPM processing inherently occurs at elevated temperatures, typically between 110 degrees Celsius and 130 degrees Celsius, though temperatures up to 220 degrees Celsius may be achieved in specific implementations. The minimum practical temperature for effective SPM processing is approximately 80 degrees Celsius, as the reaction kinetics become prohibitively slow below this threshold.

At the completion of each operation 611 performed during operation 602, a thorough rinsing with deionized water can be performed using spray bars 290 shown in FIG. 2A to prevent cross-contamination between incompatible chemistries. In some embodiments, DI water is provided to the surface of the substrate by one of a plurality of fluid dispense arms disposed within the processing chamber. In one example, the rinsing procedure following SPM treatment typically begins with hot deionized water at temperatures between 70 degrees Celsius and 80 degrees Celsius, transitioning gradually to room temperature water as rinsing progresses. This temperature gradient approach prevents thermal shock to the substrate and addresses the higher viscosity of sulfuric acid, which becomes more difficult to rinse effectively if immediately contacted with room temperature water.

As discussed above, the processing assembly 200 can employ specialized drain switching mechanisms to segregate incompatible chemistries during the cleaning and rinsing operations performed during operation 602. Separate drain paths can be implemented for acidic chemistries (e.g., HF, SC2, SPM), solvent chemistries (e.g., IPA, DMSO, DMAC, etc.), and basic/caustic chemistries (e.g., SC1), with automated valves directing effluent as shown in FIG. 2A to the appropriate collection systems. This separation provides advantages from both safety and environmental perspectives, as mixing of certain chemicals, particularly acids and bases, can potentially form hazardous compounds or low-explosive chemical salts that pose safety risks. Additionally, the drainage system for colloidal solutions may be separated from both acid and base paths, allowing potential recovery and recycling of valuable colloidal materials.

At the completion of operation 602, the substrate surface will be prepared for the subsequent material deposition processes found in operation 604. In one example, when a hydrophilic surface is desired, which is utilized in some embodiments for nanocrystalline diamond seed deposition process, an oxidizer-containing chemistry such as SC1, SC2, or SPM is employed as the final chemical cleaning step. In one example, the completion of operation 602 creates a thin chemical oxide layer between 0.5 nanometers and 2 nanometers thick, most commonly in the range of 0.5 to 0.8 nanometers, that exhibits hydrophilic properties. The hydrophilic surface characteristic can be advantageous as it minimizes the potential for defect or particle attachment compared to hydrophobic surfaces. Alternatively, in some embodiments, when a hydrophobic surface is required, a dilute HF treatment may be implemented as the final preparation step during operation 602, creating a hydrogen-terminated surface with hydrophobic properties. This substrate preparation can be important for a subsequent colloidal deposition process performed during operation 621, shown in FIG. 6, which can directly affect the quality of the properties of the deposited diamond-containing film.

Next, at operation 604, a material deposition operation process sequence is performed on the surface 115A of the substrate 115. In some embodiments of operation 604, a material deposition operation 621 and an optional rinse operation 623 are performed. During the material deposition operation 621, in one embodiment, a colloidal solution comprises nanocrystalline diamond seed particles suspended in a solvent is deposited onto the surface 115A of the substrate 115. As shown in FIG. 2B, the colloid containing fluid sources 202 each contain the prepared colloidal solution. The colloid containing fluid sources 202 are typically configured to maintain uniform colloidal suspension throughout processing operations.

As discussed above, to improve the uniform deposition of the particles within the colloid-containing fluid on the surface of the substrate, sonic energy in the form of sonic waves can be provided at a desired frequency to the colloid containing fluid to avoid agglomeration and promote particle dispersion within the colloid-containing fluid and uniform dispersion of the colloid particles across the surface 115A of the substrate 115 during operation 604. While the general frequency range of 100 to 5000 kilohertz can be used, specific implementations may target narrower frequency bands based on particular deposition process requirements. Frequencies clustered around 1.0±0.2 megahertz (MHz) are believed to have particular effectiveness in balancing dispersion performance with process stability. The power levels applied at these frequencies typically range from 100 watts to 1000 watts depending on vessel size, solution volume, and specific dispersion requirements, with power densities generally maintained between 0.1 and 1.0 watts per cubic centimeter of solution volume to ensure adequate energy for dispersion while avoiding excessive heating or solution degradation.

The solution temperature during operation 621 is typically maintained at room temperature, though elevated temperatures up to 80 degrees Celsius may be utilized for specific applications. For implementations requiring temperature management, the substrate support can be thermally regulated to maintain consistent surface temperature, preventing condensation or premature evaporation effects that might compromise deposition uniformity.

During the material deposition operation 621, the substrate rotates at controlled speeds ranging from 50 RPM to 1500 RPM, such as between 50 RPM to 500 RPM, with the specific rotation rate selected based on process phase, substrate diameter, and material characteristics. For standard 300 mm substrate processing, rotation speeds between 500 RPM and 600 RPM provide a balance between uniform distribution and adequate residence time. For specialized applications or larger substrates, speeds up to 1200 RPM or 1500 RPM may be employed. The rotation creates centrifugal forces that aid in solution distribution while simultaneously thinning the liquid layer to optimize particle density in the deposited layer.

As illustrated in FIG. 2A, the mechanical components for colloidal solution delivery include shaft 224 coupled to drive motor 222, which controls both rotational motion and horizontal positioning. The shaft 224 incorporates internal fluid passages enabling delivery of processing chemistries to the substrate backside through opening 225 from fluid source 223. The fluid delivery configuration may be arranged to optimize distribution based on substrate diameter and rotation speed, ensuring even application across the entire substrate surface.

During operation 621, the colloidal material containing mixture, such as the first colloid containing fluid 202A, is provided to the surface 115A of the substrate 115 by use of a nozzle 243 while the substrate 115 is rotated. In general, the nozzle mechanism 241 shown in FIG. 2A may incorporate one or more nozzles 243 with distinct orientations relative to the substrate surfaces. In embodiments utilizing multiple nozzles 243, a first nozzle may be oriented at angles between 30-50 degrees relative to the substrate surface, optimized for dynamic fluid interaction, while a second nozzle may be oriented at 80-100 degrees, approaching perpendicular orientation for direct impingement. The flow rates through these nozzles range from 0.5-10 milliliters per minute, selected based on solution properties, substrate diameter, and rotation speed to ensure uniform colloidal material distribution across the entire substrate surface.

As discussed above, in some embodiments, a nozzle assembly 291 is used during operation 621 to deliver the colloidal material containing mixture in an aerosol form to the surface 115A of the substrate 115, while the substrate 115 is rotated. For example, the mixture may have a droplet size between about 1 micron and about 20 microns when the mixture contacts the substrate surface 115A.

In an alternate embodiment of operation 621, a uniform deposition of colloid particles is provided onto the substrate surfaces using a direct substrate immersion process performed within a tank that includes the first colloid-containing fluid 202A. In this deposition process sequence, the substrate is positioned on the substrate support mechanisms, or retained by a robot, and immersed in the processing container containing the sonicated first colloid containing fluid 202A. A robot, such as a walking beam substrate robot assembly, with its associated substrate gripper, is configured to retain and transfer a substrate between processing positions within the processing container and other substrate receiving positions within the wet-processing system.

Following deposition of the colloidal material containing mixture, the substrate 115 will typically undergo subsequent processing steps, including the optional deionized water rinse to remove excess colloidal material, a spin dry process to remove the excess deionized water applied to the surface of the substrate, and a baking process at temperatures between 80 degrees Celsius and 130 degrees Celsius. This thermal treatment process during operation 604 can be used to drive off the solvent and promote adhesion of the nanocrystalline diamond seed particles to the substrate surface 115A. It is believed that the processes described herein will primarily promote bonding or adhesion of the colloid particles to the surface 115A of the substrate 115 by use of Van der Waals forces. The simplified architecture of this embodiment, while offering reduced complexity compared to more conventional approaches, maintains the fundamental process sequence that ensures effective nanocrystalline diamond seed deposition for subsequent diamond film growth applications.

Next, at operation 623, a stream 213 that includes a rinsing fluid is provided to a surface 115A of the substrate 115 positioned on a substrate supporting surface of a substrate support that is disposed within the processing assembly 200. The rinse fluid stream 213 (FIG. 2B) will include the delivery of a rinse agent, such as DI water, over the substrate surface 115A. In some embodiments, operation 623 includes the delivery of deionized (DI) water to remove any excess colloidal mixture from the substrate surface 115A. As illustrated in FIG. 6, operation 623 follows the colloidal deposition operation 621 and precedes the thermal treatment step 606 in the unified process flow. The rinse operation can be performed as the substrate rotating at speeds typically between 10 RPM and 1000 RPM, with specific implementations commonly utilizing approximately 500 RPM to 600 RPM. The deionized water can be dispensed through a multi-nozzle arrangement similar to the nozzle mechanism 241 shown in FIG. 2A that ensures complete coverage of the substrate surface, with flow rates typically between 0.5 liters per minute and 2 liters per minute depending on substrate diameter and rotation speed. The spray bars 290 can also be utilized for delivering the rinsing solution during this process. After the rinsing operation has been performed, the substrate can then be rotated at a drying operation spin speed, which is typically between 1000 RPM and 1800 RPM.

Operation 623 can serve multiple useful functions in the overall process sequence. Primarily, operation 623 is configured to remove excess colloidal solution from the substrate surface 115A, thereby preventing over-deposition of nanocrystalline diamond seeds that could lead to non-uniform colloidal material coverage. Additionally, the rinsing operation can be used to remove any loosely attached colloidal material particles (e.g., diamond particles) that have not properly adhered to the substrate surface 115A, leaving only those particles with sufficient attachment force to withstand the fluid shear forces generated during the rinsing process. This selective removal mechanism ensures that the remaining diamond seeds possess adequate adhesion strength to survive subsequent processing steps. Operation 623 may employ drain switching mechanisms similar to those described for the pre-deposition cleaning operations, with separate drain paths for the colloidal solution and the rinse water. This separation allows for potential recovery and recycling of valuable colliodal particles contained in the excess colloidal solution, particularly important when utilizing higher-cost diamond seed materials.

Next, at operation 606, the layer of colloid particles deposited on the surface 115A of the substrate 115 may then undergo a series of post-deposition processing operations that are designed to promote adhesion of the colloid particles (e.g., diamond seed particles) to the substrate surface, and prepare the seeded substrate for subsequent diamond film growth.

Following operation 623, the substrate with the deposited colloidal material particles (e.g., nanocrystalline diamond seed particles) proceeds to a baking process that drives off the remaining solvent and promotes strong adhesion between the colloidal material particles and the substrate surface, corresponding to the thermal treatment operation 606 shown in FIG. 6. The baking process is typically performed on a hot plate or bake plate apparatus operating at temperatures between 80 degrees Celsius and 130 degrees Celsius, similar to the temperature-controlled substrate chuck 440 or substrate pedestal 515 shown in FIG. 5. While lower temperatures (down to approximately 50 degrees Celsius) may be employed with extended processing times, and higher temperatures (up to approximately 130 degrees Celsius) may be utilized for specialized applications, the 80-130 degrees Celsius range may be used.

The duration of operation 606 typically ranges from 60 seconds to 300 seconds, with the specific duration determined by factors including substrate material, substrate thickness, temperature setpoint, and particular solvent being removed. In some embodiments, operation 606 is performed with the substrate in a horizontal orientation on a heated substrate receiving surface, with the heat transfer occurring primarily through conduction from the heated plate to the substrate. The thermal profile during the process is carefully controlled, with temperature ramp rates typically between 5 degrees Celsius per second and 15 degrees Celsius per second during the heating phase, followed by a stabilization period at the target temperature. Temperature uniformity across the substrate surface is maintained within ±2 degrees Celsius to ensure consistent processing results independent of position on the substrate. The baking environment may be controlled through appropriate exhaust systems similar to the exhaust extraction paths that remove solvent vapors generated during the process, with specific implementations potentially incorporating inert gas purging (typically nitrogen) to minimize oxidation or contamination during the high-temperature processing. The controller 126 regulates process parameters including temperature to ensure optimal conditions.

During operation 606, the remaining a solvent (e.g., water, isopropyl alcohol, dimethylacetamide, or dimethylsulfoxide, depending on the specific implementation) within the remaining colloid material containing layer is driven off, leaving the nanocrystalline colloid particles in contact with the substrate surface 115A. The direct contact between the colloid particles and the substrate surface is believed to enable the formation of strong adhesion forces between the diamond seeds and the substrate, primarily through Van der Waals interactions. While Van der Waals forces may represent the primary adhesion mechanism, alternative or complementary bonding mechanisms may potentially contribute to the overall adhesion strength depending on the specific substrate material and surface condition. For certain substrate materials, limited chemical bonding may occur at the interface, potentially including covalent bonds between carbon atoms in the diamond structure and compatible atoms in the substrate lattice. At the outcome of operation 606 is the establishment of sufficient adhesion strength to maintain the nanocrystalline colloid particles in their deposited positions during subsequent processing operations, regardless of the specific bonding mechanisms involved.

Next, at operation 608, following operation 606, the substrate with the deposited nanocrystalline diamond seed particles is used in one or more subsequent film growth and/or processing operations. In one example, the film growth operations include using the diamond seed particles deposited during operation 621 to serve as nucleation sites for diamond film growth within an appropriate reactor chamber, such as a CVD chamber shown in FIGS. 1A and 5. The uniform distribution of nanocrystalline diamond seeds achieved through the described deposition process directly influences the quality and uniformity of the subsequently grown diamond film. The diamond film growth process typically involves exposing the seeded substrate to carbon-containing precursor gases under controlled temperature and pressure conditions that promote diamond crystal growth from the diamond seed crystals. The thermal conductivity of the resulting diamond film depends significantly on the uniformity of the initial seed layer, with non-uniform seeding potentially leading to variations in film thickness, crystalline quality, and thermal performance. By ensuring uniform diamond seed deposition through the processes described herein, the present disclosure enables the production of high-performance diamond films with consistent thermal properties for heat dissipation applications in microelectronic devices.

The transition from the colloidal deposition system to the diamond growth system may involve atmospheric exposure of the seeded substrate or may be performed under controlled environment conditions, depending on the specific implementation requirements. For applications requiring minimal contamination risk, the transition may occur within an integrated cluster tool similar to the multi-level configuration shown in FIG. 1B that maintains the substrate under vacuum (upper platform 150) or inert gas environment (lower platform 109) throughout the transfer process. For standard implementations, the seeded substrate may be transferred to a FOUP 114 shown in FIG. 1A following the baking process, with subsequent automated transfer to the diamond growth system. The diamond seeds demonstrate sufficient stability under ambient conditions to maintain their adhesion and distribution characteristics during these transfer operations, with experimental validation confirming that properly processed substrates maintain seed integrity through typical handling procedures encountered in manufacturing environments. The substrate transfer mechanism 116 within the substrate handling system 106 and the central transfer mechanism 160 shown in FIG. 1B facilitate the movement of substrates between these processing stages.

In some embodiments, operation 608 is used to form at least a partial diamond crystal containing layer over the surface 115A of the substrate 115. In some embodiments, a diamond crystal layer that includes a thickness of between 2 nanometers and 1000 nanometers, such as between 5 nanometers and 500 nanometers, is formed over the surface 115A of the substrate 115. After forming the diamond crystal containing layer, a plurality of layers and patterning steps can be performed to form semiconductor devices thereon. In one example, the diamond crystal containing layer can be used as a hard mask layer during a semiconductor device fabrication process. In another example, the diamond crystal containing layer can be used as a heat dissipation layer in a power device fabrication process. In another example, the diamond crystal containing layer can be an important component in devices that include high-frequency transistors and LEDs, where efficient heat dissipation is crucial to maintain performance and reliability. Integrating diamond films can significantly reduce the operating temperature of devices like Gallium Nitride (GaN) High Electron Mobility Transistors (HEMTs), thereby enhancing their longevity and reliability.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, objects A and C may still be considered coupled to one another, even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method of forming a layer, comprising:
delivering a cleaning solution to a surface of a substrate;
delivering a first rinsing solution to the surface of the substrate to form a rinsed surface of the substrate;
delivering a colloidal containing solution to the rinsed surface of the substrate, wherein delivering a colloidal containing solution comprises delivering, by a transducer, sonic waves to the colloidal containing solution while the colloidal containing solution is delivered to the rinsed surface to form a colloidal material containing layer;
delivering a second rinsing solution to the colloidal material containing layer formed on the surface of the substrate; and
heating the colloidal material containing layer and the substrate to a first processing temperature.

2. The method of claim 1, wherein:
the colloidal containing solution comprises nanocrystalline diamond seed particles suspended in a solvent, and
the colloidal material containing layer comprises nanocrystalline diamond seed particles that have a size distribution range of 2 nanometers to 200 nanometers.

3. The method of claim 1, wherein delivering the sonic waves comprises applying sonic energy at a frequency within a range of 100 to 5000 kilohertz.

4. The method of claim 1, wherein delivering the colloidal containing solution to the rinsed surface of the substrate comprises:
dispensing the colloidal containing solution onto the rinsed surface of the substrate through an aerosol jet spray nozzle configured to combine the colloidal containing solution with a stream of gas.

5. The method of claim 1, wherein
delivering the colloidal containing solution to the rinsed surface of the substrate comprises delivering through an exit port of a nozzle a stream of the colloidal containing solution to the rinsed surface, and
the transducer is configured to provide the sonic waves to the stream of the colloidal containing solution.

6. The method of claim 1, wherein delivering the colloidal containing solution further comprises combining:
a first solution that comprises a first concentration of diamond particles in a first solvent; and
second solution, which comprises the first solvent, to form the colloidal containing solution,
wherein the concentration of the diamond particles in the colloidal containing solution is less than the first concentration of diamond particles.

7. The method of claim 1, wherein the substrate comprises silicon or glass.

8. The method of claim 7, wherein the substrate comprises a rectangle shaped panel having a length or a width between 300 millimeters and 600 millimeters.

9. The method of claim 1, wherein delivering the cleaning solution to the surface of the substrate comprises:
delivering at least one of a plurality of cleaning solutions to the surface of the substrate, wherein the plurality of cleaning solutions comprise:
an SC1 cleaning solution that contains ammonium hydroxide, hydrogen peroxide, and deionized water at a temperature ranging from room temperature to 80 degrees Celsius;
a dilute solution of hydrofluoric acid; and
an SC2 cleaning solution comprising hydrochloric acid, hydrogen peroxide, and deionized water, maintained at a temperature between 60 and 70 degrees Celsius.

10. The method of claim 1, wherein heating the colloidal material containing layer and the substrate to the first processing temperature comprises heating the substrate to a temperature between 80 degrees Celsius and 130 degrees Celsius.

11. A method of depositing a layer, comprising:
delivering, in a first processing chamber of a processing system, a cleaning solution to a surface of a substrate to form a clean surface on the substrate;
delivering, in the first processing chamber, a first rinsing solution to the clean surface of the substrate;
transferring the substrate from the first processing chamber to a second processing chamber disposed within the processing system;
delivering, in the second processing chamber, a colloidal containing solution to the surface of the substrate to form a colloidal material containing layer on the surface, wherein delivering the colloidal containing solution comprises delivering sonic waves to the colloidal containing solution while the colloidal containing solution is delivered to the surface;
delivering, in the second processing chamber, a second rinsing solution to the surface of the substrate that includes the colloidal material containing layer;
transferring the substrate from the second processing chamber to a third processing chamber disposed within the processing system; and
heating, in the third processing chamber of the processing system, the colloidal material containing layer and substrate to a first processing temperature.

12. The method of claim 11, wherein:
the colloidal containing solution comprises nanocrystalline diamond seed particles suspended in a solvent, and
the colloidal material containing layer comprises nanocrystalline diamond seed particles that have a size distribution range of 2 nanometers to 200 nanometers.

13. The method of claim 11, wherein delivering the colloidal containing solution comprises:
storing the colloidal containing solution in a storage vessel having one or more piezoelectric transducers, wherein the one or more piezoelectric transducers are positioned below a liquid level of the colloidal containing solution in the storage vessel; and
delivering the sonic waves to the colloidal containing solution while the colloidal containing solution is delivered to the surface further comprises dispensing the colloidal containing solution through a nozzle onto the surface of the substrate.

14. The method of claim 11, wherein:
the heating is performed on a bake plate within the processing system; and
the first processing temperature is between 50 degrees Celsius and 130 degrees Celsius.

15. The method of claim 11, wherein delivering the colloidal containing solution to the surface of the substrate comprises:
dispensing the colloidal containing solution onto the surface of the substrate through an aerosol jet spray nozzle configured to mix the colloidal containing solution with a gas stream to form aerosolized droplets.

16. The method of claim 11, wherein delivering the colloidal containing solution to the surface of the substrate comprises:
dispensing a stream of the colloidal containing solution onto the surface of the substrate through a nozzle that is coupled to a transducer.

17. The method of claim 16, wherein the stream of the colloidal containing solution is formed at an exit port of a nozzle, and the transducer is configured to provide the sonic waves to the stream of the colloidal containing solution.

18. The method of claim 11, wherein delivering the colloidal containing solution to the surface of the substrate further comprises:
positioning the substrate on a rotatable support within the second processing chamber;
rotating the substrate at a speed between 50 RPM and 1500 RPM while delivering the colloidal containing solution from a dispensing arm; and
adjusting the rotational speed of the dispensing arm to match an angular velocity of the rotating substrate at different radial positions to provide uniform exposure time to the colloidal containing solution across the surface.

19. The method of claim 11, wherein delivering the cleaning solution to the surface of the substrate comprises:
sequentially delivering one of a plurality of cleaning solutions to the surface of the substrate, wherein the plurality of cleaning solutions comprise:
an SC1 cleaning solution comprising ammonium hydroxide, hydrogen peroxide, and deionized water at a temperature between room temperature and 70 degrees Celsius;
a dilute hydrofluoric acid solution; and
an SC2 cleaning solution comprising hydrochloric acid, hydrogen peroxide, and deionized water at a temperature between 60 and 70 degrees Celsius.

20. The method of claim 11, wherein delivering the colloidal containing solution comprises combining:
a first solution that comprises a first concentration of diamond particles in a first solvent; and
a second solution, which comprises the first solvent, to form the colloidal containing solution,
wherein the concentration of the diamond particles in the colloidal containing solution is less than the first concentration of diamond particles.
